(19) United States
(12) Patent Application Publication
(10) Pub. No.: US 2020/0235756 A1
(43) Pub. Date: Jul. 23, 2020

(54) INTERMEDIATE TRANSFER UNIT THAT BUFFERS TENSION THAT BACKUP ROLLER RECEIVES FROM INTERMEDIATE TRANSFER BELT, AND IMAGE FORMING APPARATUS

(71) Applicant: KYOCERA Document Solutions Inc., Osaka (JP)

(72) Inventor: Takashi MORITA, Osaka (JP)

(73) Assignee: KYOCERA Document Solutions Inc., Osaka (JP)

(21) Appl. No.: 16/733,773

(22) Filed: Jan. 3, 2020

(30) Foreign Application Priority Data
Jan. 22, 2019 (JP) 2019-008510

(51) Int. Cl. H03M 13/27; H04L 1/00; H03M 13/00

(52) U.S. Cl. CPC H03M 13/2778; H03M 13/2757; H04L 1/0071; H03M 13/6502; H03M 13/271; H03M 13/2707; H03M 13/2782; H03M 13/2767; H03M 13/2742

(57) ABSTRACT

An intermediate transfer unit includes a drive roller, a tension roller, a backup roller, an intermediate transfer belt having an endless shape, a tension roller support part, a first elastic member, a backup roller support part, and a second elastic member. The backup roller support part supports the backup roller in a state of applying tension to the intermediate transfer belt in a second outward direction different from the first outward direction. The second elastic member is provided at the backup roller support part and receives, through the backup roller, the tension that the backup roller receives from the intermediate transfer belt to thereby buffer the tension.

### INCORPORATION BY REFERENCE

This application claims priority to Japanese Patent Application No. 2019-008510 filed on 22 Jan., 2019, the entire contents of which are incorporated by reference herein.

### BACKGROUND

The present disclosure relates to an image forming apparatus such as a multifunction peripheral and a printer, and particularly relates to a technique for suppressing vibration of an intermediate transfer belt of an intermediate transfer unit.

As a general image forming apparatus, there is a known image forming apparatus in which a toner image is formed on a surface of an image carrier (photosensitive drum), an endless intermediate transfer belt is circularly moved while the intermediate transfer belt is being pressured to the image carrier by a transfer roller, the toner image is primarily transferred from the image carrier to the intermediate transfer belt, and the toner image is thereafter secondary transferred from the intermediate transfer belt to a recording sheet.

The endless intermediate transfer belt is stretched over, for example, a drive roller, a tension roller, and a backup roller, and circularly moved. The drive roller is rotationally driven, and circularly moves the intermediate transfer belt. The tension roller is urged by a spring or the like in an outward direction of the intermediate transfer belt, and applies tension to the intermediate transfer belt. The backup roller forms and holds a part of a rotation track of the intermediate transfer belt.

### SUMMARY

A technique improved over the above technique is proposed as one aspect of the present disclosure.

An intermediate transfer unit according to an aspect of the present disclosure includes a drive roller, a tension roller, a backup roller, an intermediate transfer belt having an endless shape, a tension roller support part, a first elastic member, a backup roller support part, and a second elastic member. The intermediate transfer belt is stretched over the drive roller, the tension roller, and the backup roller, and moves circularly. The tension roller support part freely movably supports the tension roller in inner and outer directions of the intermediate transfer belt. The first elastic member urges the tension roller in a first outward direction of the intermediate transfer belt and applies tension to the intermediate transfer belt through the tension roller. The backup roller support part supports the backup roller in a state of applying tension to the intermediate transfer belt in a second outward direction different from the first outward direction. The second elastic member is provided at the backup roller support part and receives, through the backup roller, the tension that the backup roller receives from the intermediate transfer belt to thereby buffer the tension.

An intermediate transfer unit according to another aspect of the present disclosure includes a drive roller, a tension roller, a backup roller, an intermediate transfer belt having an endless shape, a tension roller support part, a first elastic member, and a backup roller support part. The intermediate transfer belt is stretched over the drive roller, the tension roller, and the backup roller, and moves circularly. The tension roller support part freely movably supports the tension roller in inner and outer directions of the intermediate transfer belt. The first elastic member urges the tension roller in a first outward direction of the intermediate transfer belt and applies tension to the intermediate transfer belt through the tension roller. The backup roller support part supports the backup roller in a state of applying tension to the intermediate transfer belt in a second outward direction different from the first outward direction. The backup roller includes an elastic layer having a cylindrical shape, and a surface layer, the elastic layer being reversibly deformable and being provided around a rotation axis of the backup roller, the surface layer being formed of a material harder than the elastic layer and being provided at a surface of the elastic layer.

An image forming apparatus according to another aspect of the present disclosure includes an image forming device that includes the intermediate transfer unit described above and transfers a toner image formed on a surface of the intermediate transfer belt onto a recording sheet to form an image on the recording sheet.

### BRIEF DESCRIPTION OF THE DRAWINGS

FIG. 1 is a cross-sectional view showing an image forming apparatus according to one embodiment of the present disclosure.

FIG. 2 is a side view showing an intermediate transfer unit according to a first embodiment.

FIG. 3 is a schematic perspective view showing an intermediate transfer belt of the intermediate transfer unit according to the first embodiment when viewed from below.

FIG. 4 is a schematic perspective view showing a tension roller, a backup roller, and other parts of the intermediate transfer unit according to the first embodiment when viewed from below.

FIG. 5A and FIG. 5B are enlarged side views each showing a portion of a primary transfer roller, the tension roller, the backup roller, and other parts of the intermediate transfer unit according to the first embodiment.

FIG. 6 is an enlarged perspective view showing an inner peripheral surface portion of the intermediate transfer belt stretched over the drive roller and the tension roller.

FIG. 7 is an enlarged side view showing a primary transfer roller, a tension roller, a backup roller, and other parts of an intermediate transfer unit according to a second embodiment.

FIG. 8 is a cross-sectional view showing the backup roller of the intermediate transfer unit according to the second embodiment.

### DETAILED DESCRIPTION

Hereinafter, a description will be given of an intermediate transfer unit and an image forming apparatus, both according to an embodiment of the present disclosure, with reference to the drawings.

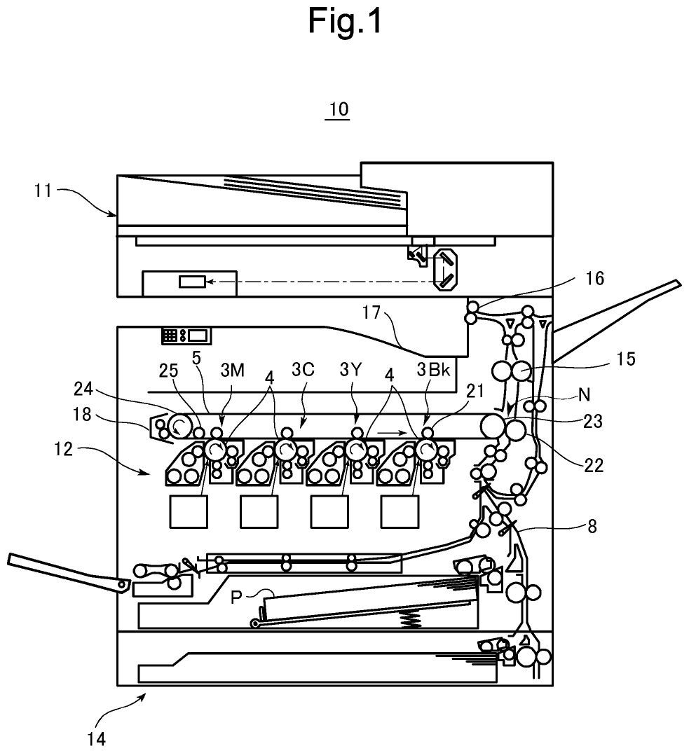

FIG. 1 is a cross-sectional view showing the image forming apparatus according to one embodiment of the present disclosure. The image forming apparatus 10 is a multifunction peripheral (MFP) having multiple functions including, for example, a copy function, a print function, and a facsimile function. The image forming apparatus 10 includes an image reading device 11 and an image forming device 12.

The image reading device 11 includes an image pick-up device that optically reads an image of an original document. The image reading device 11 converts analog output of this image pick-up device into a digital signal and generates image data indicating the image of the original document.

The image forming device 12 forms the image indicated by the image data on a recording sheet. The image forming device 12 is made up by including an image forming device 3M for magenta, an image forming device 3C for cyan, an image forming device 3Y for yellow, and an image forming device 3Bk for black. Each of these image forming devices 3M, 3C, 3Y, and 3Bk uniformly charges a surface of a photosensitive drum 4, exposes the surface of the photosensitive drum 4 to light to form an electrostatic latent image on the surface of the photosensitive drum 4, and develops the electrostatic latent image on the surface of the photosensitive drum 4 into a toner image.

An intermediate transfer belt 5 has an endless shape and stretched over a drive roller 23, a tension roller 24, and a backup roller 25, and moves circularly through being driven by the drive roller 23. When the intermediate transfer belt 5 moves circularly, the toner image formed on the surface of each photosensitive drum 4 is primarily transferred to a surface of the intermediate transfer belt 5 by respective primary transfer rollers 21, and superposed, and a multicolor toner image is formed on the surface of the intermediate transfer belt 5. This multicolor toner image is secondarily transferred, at a nip region N between a secondary transfer roller 22 and the drive roller 23, to a recording paper sheet P conveyed from a sheet feed unit 14 via a conveyance path 8.

Thereafter, heat and pressure are applied to the recording paper sheet P by a fixing device 15, so that the toner image on the recording paper sheet P is fixed by heat and pressure. Then, the recording paper sheet P is discharged through an ejection roller 16 to a sheet output tray 17.

Next, a detailed description will be given of an intermediate transfer unit 20 according to the first embodiment: the intermediate transfer unit 20 includes the intermediate transfer belt 5, each of the primary transfer rollers 21, the drive roller 23, the tension roller 24, and the backup roller 25.

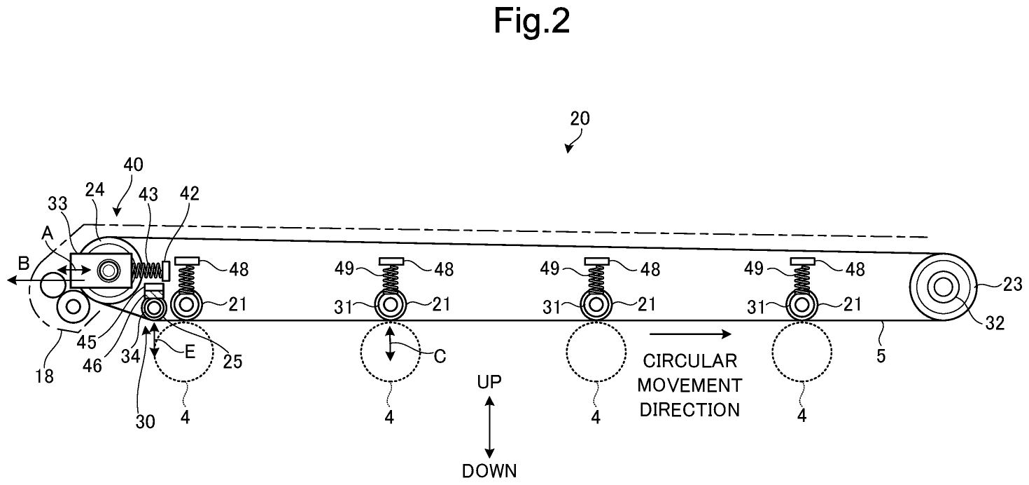

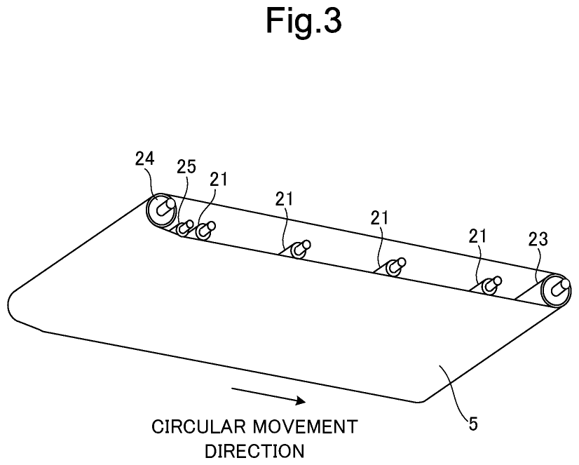

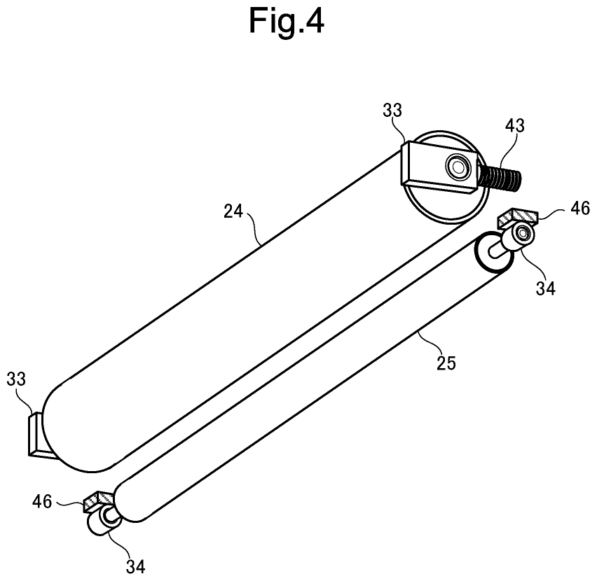

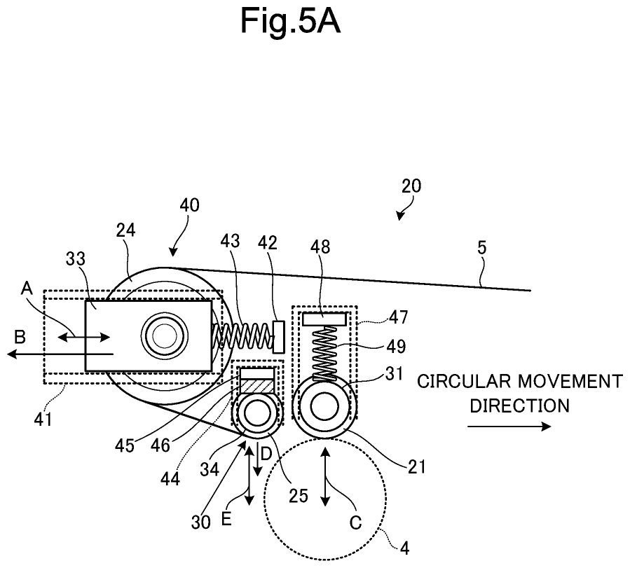

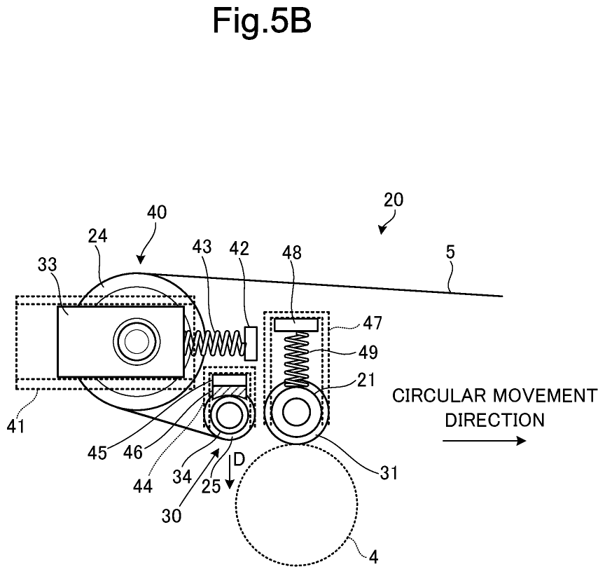

FIG. 2 is a side view showing the intermediate transfer unit 20 according to the first embodiment. FIG. 3 is a schematic perspective view showing the intermediate transfer belt 5 of the intermediate transfer unit 20 when viewed from below. FIG. 4 is a schematic perspective view showing the tension roller 24, the backup roller 25, and other parts of the intermediate transfer unit 20 when viewed from below. FIG. 5A and FIG. 5B are enlarged side views each showing a portion of the primary transfer roller 21, the tension roller 24, the backup roller 25, and other parts of the intermediate transfer unit 20.

As shown in FIG. 2 to FIG. 5B, the intermediate transfer unit 20 includes each bearing 31 of each of the primary transfer rollers 21, a bearing 32 of the drive roller 23, a bearing 33 of the tension roller 24, and a bearing 34 of the backup roller 25, all of which are provided at a main body casing of the intermediate transfer unit 20. These bearings 31-34 are respectively provided at both ends of the axis of the respective rollers and rotatably support the respective rollers.

Each of the bearings 32 provided at the both ends of the drive roller 23 is fixed to a fixed position of the main body casing of the intermediate transfer unit 20. Therefore, the drive roller 23 is rotatably supported at the fixed position.

Each of the bearings 33 provided at the both ends of the tension roller 24 is freely movably supported in inner and outer directions A orthogonal with the surface of the intermediate transfer belt 5, at inside of respective roller housings 41 provided at the main body casing of the intermediate transfer unit 20. Each stopper 42 facing the respective bearings 33 is fixed to a fixed position of the main body casing. The stoppers 42 are formed of hard resin or the like. Each spring 43 is inserted between each of the bearings 33 and each of the stoppers 42 in a compressed state. The spring 43 is a pushing spring. Each of the bearings 33 and the tension roller 24 are urged in the outer direction of the intermediate transfer belt 5 by urging force of each of the springs 43. Each of the springs 43 urges the tension roller 24 in a first outward direction B of the intermediate transfer belt 5, and applies tension to the intermediate transfer belt 5 through the tension roller 24. By this way, tension is applied to the intermediate transfer belt 5. A tension roller support part 40 supporting the tension roller 24 includes the bearings 33, the spring 43, and the stopper 42.

Each of the bearings 34 provided at the both ends of the backup roller 25 is freely movably supported in the inner and outer directions E orthogonal with the surface of the intermediate transfer belt 5 at inside of respective roller housings 44 provided at the main body casing of the intermediate transfer unit 20. Each stopper 45 facing the respective bearings 34 is fixed to a fixed position at the inside of the respective roller housings 44. Each buffer member 46 is sandwiched between each of the bearings 34 and each of the stoppers 45, and each of the buffer members 46 is pressed to the corresponding bearing 34 and the corresponding stopper 45. The backup roller 25 forms and holds a part of a rotation track of the intermediate transfer belt 5.

Each of the buffer members 46 is formed of reversibly deformable elastic material: for example, a expandable synthetic resin, such as polyurethane foam, or a rubber. It is preferable to use a material having a large loss coefficient for the buffer member 46. The buffer member 46 is compressed when the bearing 34 receives a load by the tension from the intermediate transfer belt 5; the buffer member 46 returns to its uncompressed original state when the bearing 34 is not receiving the load. The compression direction of the buffer member 46 is arranged to be the same direction as the load direction that the bearing 34 receives by the tension from the intermediate transfer belt 5.

A backup roller support part 30 supporting the backup roller 25 includes the bearing 34, the buffer member 46, and the stopper 45. The backup roller support part 30 supports the backup roller 25 in a state of applying the tension to the intermediate transfer belt 5 in the second outward direction D different from the first outward direction B. The backup roller support part 30 supports the backup roller 25 at a position where the intermediate transfer belt 5 is pushed in the second outward direction D, the outward beyond the position of the intermediate transfer belt 5 assuming that there is no backup roller 25.

Each of the bearings 31 provided at the both ends of the primary transfer roller 21 is freely movably supported in inner and outer directions C (vertical direction) orthogonal with the surface of the intermediate transfer belt 5 at inside of respective roller housings 47 provided at the main body casing of the intermediate transfer unit 20. Each stopper 48 facing the respective bearings 31 is fixed to the fixed position at inside of respective roller housings 47. Each spring 49 is inserted between each of the bearings 31 and each of the stoppers 48 in a compressed state. Each of the bearings 31 and the corresponding primary transfer roller 21 are urged in the outer direction of the intermediate transfer belt 5 by urging force of each of the springs 49. Thereby the primary transfer roller 21 is pressed to the photosensitive drum 4 through the intermediate transfer belt 5.

The intermediate transfer belt 5 is stretched over the above described drive roller 23, tension roller 24, and backup roller 25, and each of the primary transfer rollers 21 is pressed to the respective photosensitive drums 4 through the intermediate transfer belt 5. When the drive roller 23 is rotationally driven under this state, the intermediate transfer belt 5 makes contact with each of the photosensitive drums 4 while circularly moving, and the toner images in the respective colors are transferred from each of the photosensitive drums 4 to the intermediate transfer belt 5. A belt cleaning device 18 removes toner remaining on the surface of the intermediate transfer belt 5.

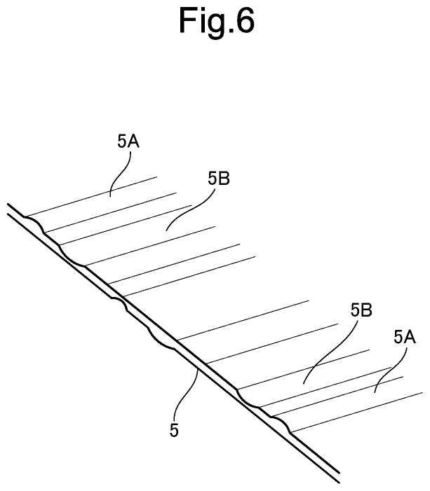

FIG. 6 is an enlarged perspective view showing an inner peripheral surface portion of the intermediate transfer belt 5 when it is stretched over the drive roller 23 and the tension roller 24. Under the aforesaid state where the tension is applied to the intermediate transfer belt 5 by the tension roller 24, the intermediate transfer belt 5 is pressed to the backup roller 25 by the tension of the intermediate transfer belt 5. The intermediate transfer belt 5 is formed by extrusion-molding. There is a case where small ridges 5A and grooves 5B extending in the width direction of the intermediate transfer belt 5 are formed on the inner peripheral surface of the intermediate transfer belt 5 at the time of the extrusion-molding, as shown in FIG. 6. When the intermediate transfer belt 5 is moved circularly while such the small ridges 5A and grooves 5B of the inner peripheral surface of the intermediate transfer belt 5 are pressed to the backup roller 25, minute vibration is generated on the intermediate transfer belt 5. The above-mentioned general image forming apparatus takes no countermeasure for this minute vibration of the intermediate transfer belt 5. Accordingly, the minute vibration is transmitted to a shaft of the backup roller 25 and so on, resonating the intermediate transfer belt 5 and the backup roller 25: there is a case where the vibration of the intermediate transfer belt 5 becomes large particularly between the tension roller 24 and the backup roller 25, and abnormal noise is generated around the intermediate transfer belt 5 and the backup roller 25. The above-mentioned general image forming apparatus does not take countermeasures against such abnormal noise generated around the intermediate transfer belt 5 and the backup roller 25.

In contrast, in the first embodiment described above, the buffer member 46 is sandwiched between the bearing 34 of the backup roller 25 and the stopper 45. In addition, at the portion of the backup roller 25, the intermediate transfer belt 5 can be displaced freely in the inner and outer directions E. Therefore, when the minute vibration appears at the intermediate transfer belt 5, this vibration is transmitted from the backup roller 25 through its corresponding bearing 34 to the buffer member 46, and the buffer member 46 deforms according to the displacement of the inner and outer directions E of the intermediate transfer belt 5 so as to absorb the vibration. For example, when the backup roller 25 receives the pressure in the inner and outer directions E by the ridges 5A and the grooves 5B, the buffer member 46 deforms from the previous state shown in FIG. SA to the state shown in FIG. 5B. Furthermore, when the pressure is released, the buffer member 46 returns from the state shown in FIG. 5B to the state shown in FIG. 5A. That is, when the minute vibration is transmitted to the buffer member 46 from the backup roller 25 through its corresponding bearing 34, the vibration is damped as the buffer member 46 deforms according to the displacement of the inner and outer directions E of the intermediate transfer belt 5. This allows the vibration of the intermediate transfer belt 5 be suppressed, and the generation of abnormal noise around the intermediate transfer belt 5 and the backup roller 25 be prevented, thus the abnormal noise can be reduced.

The buffer member 46 formed of the expandable synthetic resin or the rubber is presented as an example in the first embodiment. Alternatively, followings may be applied to the first embodiment: (i) using the buffer member 46 formed of the pushing spring; (ii) using the buffer member 46 formed of a combination of the expandable synthetic resin, being a material reversibly deformable, or the rubber and the spring; or (iii) using the buffer member 46 formed of a combination of the expandable synthetic resin, the rubber, and the spring.

Next, an intermediate transfer unit 50 according to a second embodiment will be described.

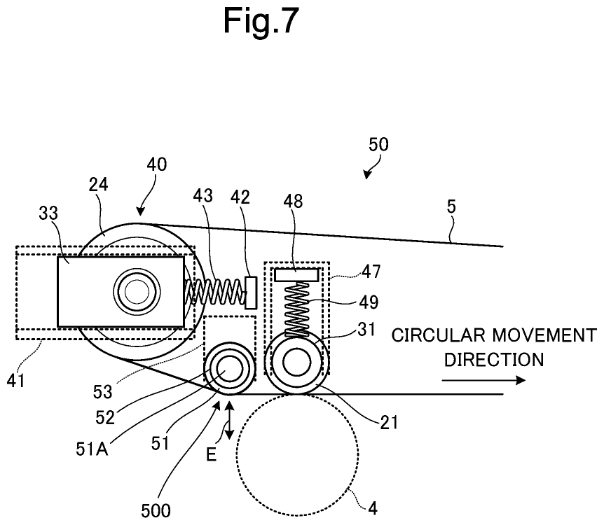

FIG. 7 is an enlarged side view showing the primary transfer roller 21, the tension roller 24, the backup roller 51, and other parts of an intermediate transfer unit 50 according to the second embodiment.

The intermediate transfer unit 50 according to the second embodiment is to be applied to the image forming apparatus 10 shown in FIG. 1 similar to the intermediate transfer unit 20 according to the first embodiment, and has the intermediate transfer belt 5, each of the primary transfer rollers 21, the drive roller 23, and the tension roller 24: the difference is in that a backup roller 51 is provided in the intermediate transfer unit 50 according to the second embodiment in place of the backup roller 25 of the intermediate transfer unit 20 according to the first embodiment. The tension roller support part 40 supporting the tension roller 24 includes the bearings 33, the spring 43, and the stopper 42.

Each of the bearings 52 provided at the both ends of the backup roller 51 is fixed to a fixed position at inside of respective roller housings 53 provided at the main body casing of the intermediate transfer unit 50. Therefore, the backup roller 51 is freely rotatably supported at the fixed position.

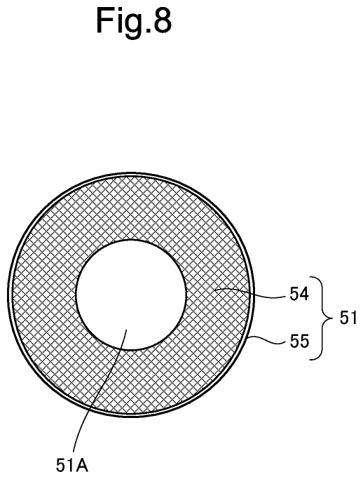

As shown in FIG. 8, the backup roller 51 includes: an elastic layer 54 having a cylindrical shape and being provided around an axis 51A of the backup roller 51; and a surface layer 55 being provided at a surface of the elastic layer 54. For example, the elastic layer 54 is formed of an expandable synthetic resin, such as urethane foam, being reversibly deformable, or formed of a rubber. The surface layer 55 is, for example, formed of a hard material, such as a metal, and is processed so that the surface portion slips (to reduce friction with the intermediate transfer belt 5). The axis 51A, the elastic layer 54, and the surface layer 55 rotate together. A backup roller support part 500 supporting the backup roller 51 includes bearings of the axis 51A.

Here assumed that, like above described, the intermediate transfer belt 5 is moved circularly while the small ridges 5A and grooves 5B of the inner peripheral surface of the intermediate transfer belt 5 are pressed to the backup roller 51, thereby the minute vibration is generated on the intermediate transfer belt 5. In this case, the vibration of the intermediate transfer belt 5 is transferred to the elastic layer 54 through the surface layer 55 of the backup roller 51, the elastic layer 54 having the cylindrical shape deforms according to the displacement of the inner and outer directions E of the intermediate transfer belt 5 so as to absorb the vibration, and the vibration is damped. This allows the vibration of the intermediate transfer belt 5 be suppressed, thus the generation of abnormal noise can be prevented.

Furthermore, since the surface of the backup roller 51 is provided with the surface layer 55, by the rotation of the backup roller 51 and the sliding of the surface layer 55 with respect to the intermediate transfer belt 5, it is possible to smoothly move the intermediate transfer belt 5 circularly.

The first embodiment and the second embodiment may be combined. That is, such the configuration includes the following: in the intermediate transfer unit 20 according to the first embodiment, each of the bearings 52 provided at the both ends of the backup roller 51 is freely movably supported in the inner and outer directions E orthogonal with the surface of the intermediate transfer belt 5 at the inside of the respective roller housings 44; and each buffer member 46 is sandwiched between each of the bearings 52 provided at the both ends of the backup roller 51 and the stopper 45 fixed to the inside of each of the roller housings 44. In this case, by both the elastic layer 54 having the cylindrical shape and the buffer member 46, which are included in the backup roller 51, the vibration of the intermediate transfer belt 5 is absorbed, thus is damped. Thereby, the vibration of the intermediate transfer belt 5 can be suppressed more effectively.

Although in the above embodiments a multicolor multifunction peripheral is used as an example of the image forming apparatus according to the present disclosure, the example is merely illustrative and other electronic apparatus, for example any other image forming apparatus, such as a copier and a facsimile machine, may be used.

The configuration and processing described with reference to FIGS. 1 to 8 are merely illustrative of the present disclosure and not intended to limit the present disclosure to the above particular configuration and processing.

While the present disclosure has been described in detail with reference to the embodiments thereof, it would be apparent to those skilled in the art the various changes and modifications may be made therein within the scope defined by the appended claims.

What is claimed is:

1. An intermediate transfer unit comprising:
a drive roller;
a tension roller;
a backup roller;
an intermediate transfer belt that has an endless shape, is stretched over the drive roller, the tension roller, and the backup roller, and moves circularly;
a tension roller support part that freely movably supports the tension roller in inner and outer directions of the intermediate transfer belt;
a first elastic member that urges the tension roller in a first outward direction of the intermediate transfer belt and applies tension to the intermediate transfer belt through the tension roller;
a backup roller support part that supports the backup roller in a state of applying tension to the intermediate transfer belt in a second outward direction different from the first outward direction; and
a second elastic member that is provided at the backup roller support part and receives, through the backup roller, the tension that the backup roller receives from the intermediate transfer belt to thereby buffer the tension.

2. The intermediate transfer unit according to claim 1, wherein
the backup roller support part includes a bearing of the backup roller and a stopper fixed to a fixed position, and
the second elastic member is provided in a state of being sandwiched between the bearing and the stopper.

3. The intermediate transfer unit according to claim 1, wherein the second elastic member is formed of an elastic synthetic resin or a rubber.

4. The intermediate transfer unit according to claim 1, wherein the second elastic member includes a spring.

5. The intermediate transfer unit according to claim 1, wherein the backup roller includes an elastic layer having a cylindrical shape, and a surface layer, the elastic layer being reversibly deformable and being provided around a rotation axis of the backup roller, the surface layer being formed of a material harder than the elastic layer and being provided at a surface of the elastic layer.

6. The intermediate transfer unit according to claim 5, wherein
the elastic layer is formed of an elastic synthetic resin or a rubber, and
the surface layer is formed of a metal.

7. The intermediate transfer unit according to claim 2, wherein the bearing is freely movably supported in inner and outer directions orthogonal with a surface of the intermediate transfer belt.

8. An intermediate transfer unit comprising:
a drive roller;
a tension roller;
a backup roller;
an intermediate transfer belt that has an endless shape, is stretched over the drive roller, the tension roller, and the backup roller, and moves circularly;
a tension roller support part that freely movably supports the tension roller in inner and outer directions of the intermediate transfer belt;
a first elastic member that urges the tension roller in a first outward direction of the intermediate transfer belt and applies tension to the intermediate transfer belt through the tension roller; and
a backup roller support part that supports the backup roller in a state of applying tension to the intermediate transfer belt in a second outward direction different from the first outward direction,
wherein the backup roller includes an elastic layer having a cylindrical shape, and a surface layer, the elastic layer being reversibly deformable and being provided around a rotation axis of the backup roller, the surface layer being formed of a material harder than the elastic layer and being provided at a surface of the elastic layer.

9. An image forming apparatus comprising:
an image forming device that includes the intermediate transfer unit according to claim 1 and transfers a toner image formed on a surface of the intermediate transfer belt onto a recording sheet to form an image on the recording sheet.

10. An image forming apparatus comprising:
an image forming device that includes the intermediate transfer unit according to claim 8 and transfers a toner image formed on a surface of the intermediate transfer belt onto a recording sheet to form an image on the recording sheet.
